(19) United States
(12) Patent Application Publication
(10) Pub. No.: US 2011/0291191 A1
(43) Pub. Date: Dec. 1, 2011

(54) MOS Structure with Suppressed SOI Floating Body Effect and Manufacturing Method thereof

(75) Inventors: Jing Chen, Shanghai (CN); Jiexin Luo, Shanghai (CN); Qingqing Wu, Shanghai (CN); Xiaolu Huang, Shanghai (CN); Xi Wang, Shanghai (CN)

(73) Assignee: SHANGHAI INSTITUTE OF MICROSYSTEM AND INFORMATION TECHNOLOGY, CHINESE ACADEMY, Shanghai (CN)

(21) Appl. No.: 12/937,360

(22) PCT Filed: Jul. 14, 2010
(86) PCT No.: PCT/CN10/75141

§ 371 Date: Oct. 11, 2010

(30) Foreign Application Priority Data
Jan. 28, 2010 (CN) 201010102139.9

(51) Int. Cl. H01L 29/772

(52) U.S. Cl. 257/347; 257/E29.242

(57) ABSTRACT

The present invention discloses a MOS structure with suppressed floating body effect including a substrate, a buried insulation layer provided on the substrate, and an active area provided on the buried insulation layer comprising a body region, a first conductive type source region and a first conductive type drain region provided on both sides of the body region respectively and a gate region provide on top of the body region, wherein the active area further comprises a highly doped second conductive type region between the first conductive type source region and the buried insulation layer. For manufacturing this structure, implant ions into a first conductive type source region via a mask having an opening thereon forming a highly doped second conductive type region under the first conductive type source region and above the buried insulation layer. The present invention will not increase chip area and is compatible with conventional CMOS process.

### BACKGROUND OF THE PRESENT INVENTION

1. Field of Invention

The present invention relates to a MOS (Metal Oxide Semiconductor) structure and a manufacturing method thereof, more particularly to a MOS structure with suppressed SOI floating body effect and manufacturing method thereof, which belongs to semiconductor manufacturing field.

2. Description of Related Arts

SOI means silicon on insulator. In SOI technique, device is fabricated in a very thin silicon film, and the device and substrate are separated by a buried oxide layer. This structure makes SOI have many advantages over bulk silicon technique. Small parasitic capacitance enable the high speed and low power consumption of the SOI device. Full dialectical isolation feature of SOI CMOS entirely eliminates the parasitic latch-up effect of bulk silicon CMOS device, and improve the integration density and the ability to resist radiation. SOI technique is widely used for RF, high voltage, and anti-radiation field and so on. With the size of the device continuing to shrink, SOI may become a first choice instead of bulk silicon.

SOI MOS is divided into a partially depleted SOI MOS (PDSOI) and a fully depleted SOI MOS (FDSOI) according to whether the body region of the active area is fully depleted or not. Usually, the silicon film on top of the FDSOI is very thin. Thin film SOI silicon costs high and the threshold voltage of the FDSOI is hardly controlled. Therefore, the PDSOI is commonly used.

The body region of the active area of PDSOI is not fully depleted, so that the body region is suspended. The charge due to an impact ionization mechanism can not be transferred quickly, which will result in the floating body effect. As for SOI NMOS channel, the channel electrons can acquire sufficient energy in the high electric field zone near the drain to create electrons-hole pairs, due to an impact ionization mechanism. The generated electrons rapidly move into the channel in the drain, while the holes migrate towards the place of lowest potential, the floating body, so as to raise the electric potential of the floating body. The increase of body potential gives rise to a decrease of the threshold voltage and the drain current increases, which is called Kink effect. Kink effect has many adverse effects to the performance and reliability of the device and circuit, so that the kink effect should be controlled in the design of the device. That p-channel SOI transistor is usually free of the kink effect, because the coefficient of pair generation by energetic holes is much lower than that of pair generation by energetic electrons.

In order to overcome the drawbacks of the SOI NMOS, a body contact method is used to connect the body to the source or the ground. As shown in FIGS. 1a and 1b, the P+ implantation area formed at one side of the T-shaped gate is connected to the P type body region under the gate region. When the MOS device is operating, the carriers accumulated in the body region are released through P+ passage so as to lower the electrical potential of the body region. The drawbacks of the method are that the process is complex, the parasitic effect is increased, part of the electrical performance is lowered and the area of the device is increased.

Therefore, there is a need to develop a new MOS structure with suppressed floating body effect.

### SUMMARY OF THE PRESENT INVENTION

An object of the present invention is to provide a MOS structure with suppressed floating body effect and a manufacturing method thereof.

In order to accomplish the above object, the present invention provides a MOS structure with suppressed floating body effect comprising a substrate, a buried insulation layer provided on the substrate, and an active area provided on the buried insulation layer comprising a body region, a first conductive type source region and a first conductive type drain region provided on both sides of the body region respectively and a gate region provide on top of the body region, wherein the active area further comprises a highly doped second conductive type region between the first conductive type source region and the buried insulation layer, and the highly doped second conductive type region contacts to the first conductive type source region, the buried insulation layer and the body region respectively.

The present invention further provides a method of forming a highly doped second conductive type region comprising step of implanting ions into a first conductive type source region via a mask having an opening thereon forming a highly doped second conductive type region under the first conductive type source region and above the buried insulation layer. The present invention will not increase chip area and is compatible with conventional CMOS process.

The feature of the present invention is that there is a highly doped P type region is under the source region. The highly doped P type region and highly doped N type region form a tunnel junction, so that the kink voltage of SOI MOS is postponed after the operating voltage. Therefore, the floating effect will not influence the operating of the device. The present invention will not increase chip area and is compatible with conventional CMOS process.

### BRIEF DESCRIPTION OF THE DRAWINGS

FIG. 1a is a top view of a MOS adopting body contact method to suppress the floating body effect in prior art.

FIG. 1b is a cross sectional view of a MOS adopting body contact method to suppress the floating body effect in prior art.

FIG. 2 is a sectional view of a MOS structure with suppressed floating body effect of the present invention.

FIG. 3 is a schematic view of a method of manufacturing MOS structure with suppressed floating body effect according to a first example of the present invention.

FIG. 4 is a schematic view of a method of manufacturing MOS structure with suppressed floating body effect according to a second example of the present invention.

FIG. 5 is a first schematic view of a method of manufacturing MOS structure with suppressed floating body effect according to a third example of the present invention.

FIG. 6 is a comparison chart of I_{d}-V_{d} curves of the MOS structure of the present invention and the conventional MOS.

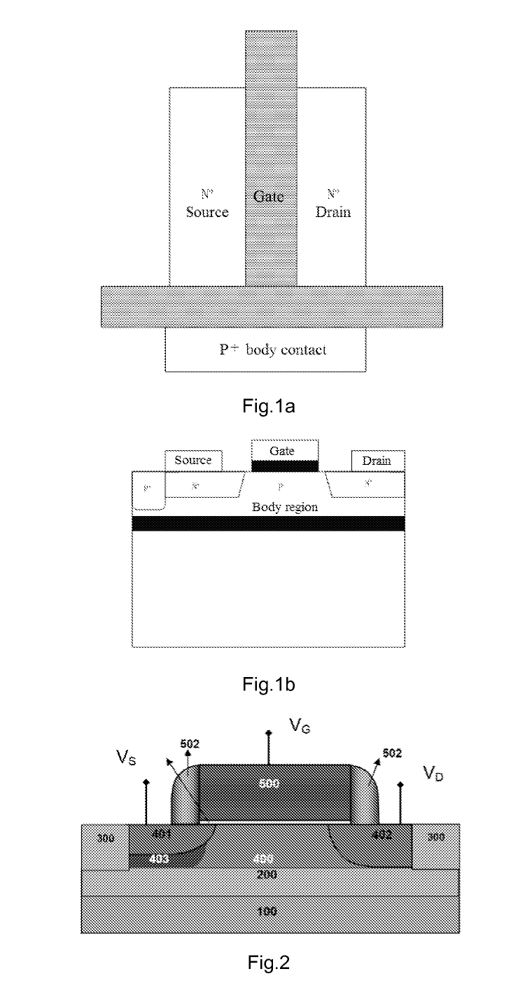

### DETAILED DESCRIPTION OF THE INVENTION

The present invention is further explained in detail according to the accompanying drawings. It should be noted that figures are schematic representations of devices, and not drawn to scale.

Referring to FIG. 2 of the drawings, a MOS structure with suppressed floating body effect is illustrated, which includes a substrate 100, a buried insulation layer 200 provided on the substrate 100, an active area provided on the buried insulation layer 200, and a shallow trench isolation (STI) structure 300 provided surrounding the active area. The active area includes a body region 400, a first conductive type source region 401 and a first conductive type drain region 402 provided on both sides of the body region 400 respectively and a gate region provide on top of the body region 400. The active area further includes a highly doped second conductive type region 403 between the first conductive type source region 401 and the buried insulation layer 200. The highly doped second conductive type region 403 contacts to the first conductive type source region 401, the buried insulation layer 200 and the body region 400 respectively. The gate region includes a gate dielectric layer 501 and a gate electrode 500 provided on the gate dielectric layer 501. An insulation dielectric spacer 502 is provided around the gate region.

The first conductive type source region 401 adopts highly doped N-type conductive material, and the first conductive type drain region 402 also adopts highly doped N-type semiconductor material. The highly doped second conductive type region 403 adopts highly doped P-type semiconductor material. The body region 400 adopts P-type semiconductor material. The semiconductor material of the active area is Si or Ge. The buried insulation layer 200 is buried oxide (BOX) that is SiO₂ layer.

A method of forming the highly doped second conductive type region 403 comprises the steps of: creating an opening at the first conductive type source region 401, implanting ions into the first conductive type source region 401 forming the highly doped second conductive type region 403 under the source region 401 and above the buried insulation layer 200. In a NMOS structure, the first conductive type is N type and the second conductive type is P type. As to NMOS structure, P type ion implantation is adopted. In the preferred embodiment, the ion is boron, the implantation energy is 9 Kev, and the dose is 3 E¹⁵/cm².

N type source region of the present invention and the P region under the N type source region form a PN junction. Two side of the PN junction are highly doped, and the barrier region is thin. Due to the tunnel effect of quantum mechanics, the PN junction easily forms tunnel junction. The difference between the tunnel junction and the PN junction is illustrated as below. The forward current of the tunnel junction rapidly increases to a maximum value with the increasing of the forward voltage. The current is mainly tunnel current. Afterwards, with the increasing of the voltage, the current is lowered to a minimum value, which is opposite to the PN junction. And then forward current increases to a maximum value with the increasing of the voltage, which is same with the PN junction. In the present invention, the tunnel current can discharge part of the accumulated charge due to the floating effect of the SOI MOS. During the phase that the feature of the tunnel junction is same with the PN junction, the body region of SOI MOS can still accumulate charge, so that the kink effect of SOI MOS is postponed. When the operating voltage is postponed after the kink voltage, the floating effect will not influence the operating of the device.

### Example I

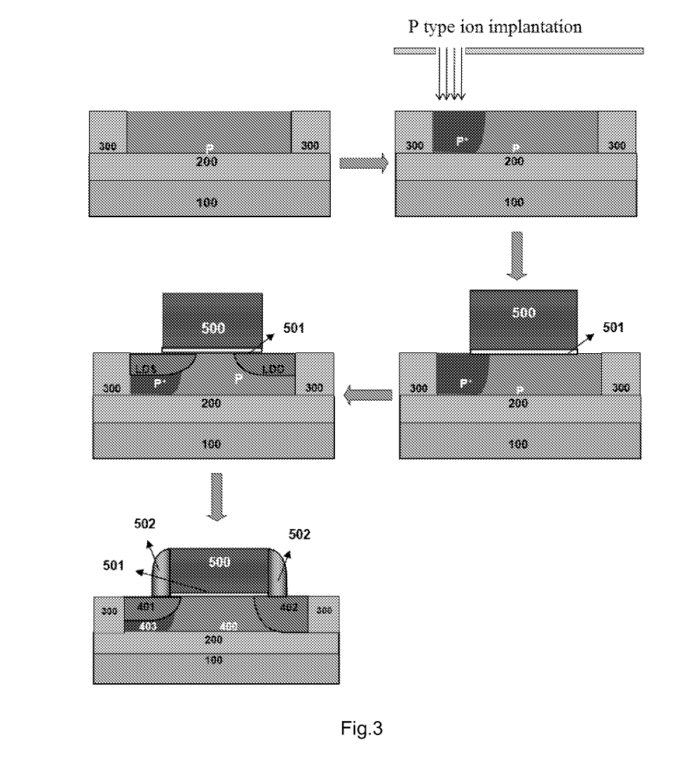

Referring to FIG. 3 of the drawings, this example provides a method of manufacturing MOS structure with suppressed floating body effect comprises the following steps.

Firstly, create a shallow trench isolation structure 300 on a semiconductor material, such as SOI (silicon on insulator) or GOI (germanium on insulator), having a buried insulation layer 200, to isolate an active area, and implant P ion into the active area. Add a mask on the active area, create an opening on the mask at a position of a first conductive type source region 401, and vertically highly implant P ions into the active area into via the mask forming a highly doped P region. Create a gate dielectric layer 501 and gate electrode 500. Lightly dope a source region and a drain region. Implant N ions into the source region and source region forming a first conductive type region 401 and a first conductive type drain region 402 and a body region 400 between the first conductive type region 401 and the first conductive type drain region 402. Form a second conductive type region 403 between the first conductive type region 401 and the buried insulation layer 200. Produce an insulation dielectric spacer 502 around the gate region.

### Example II

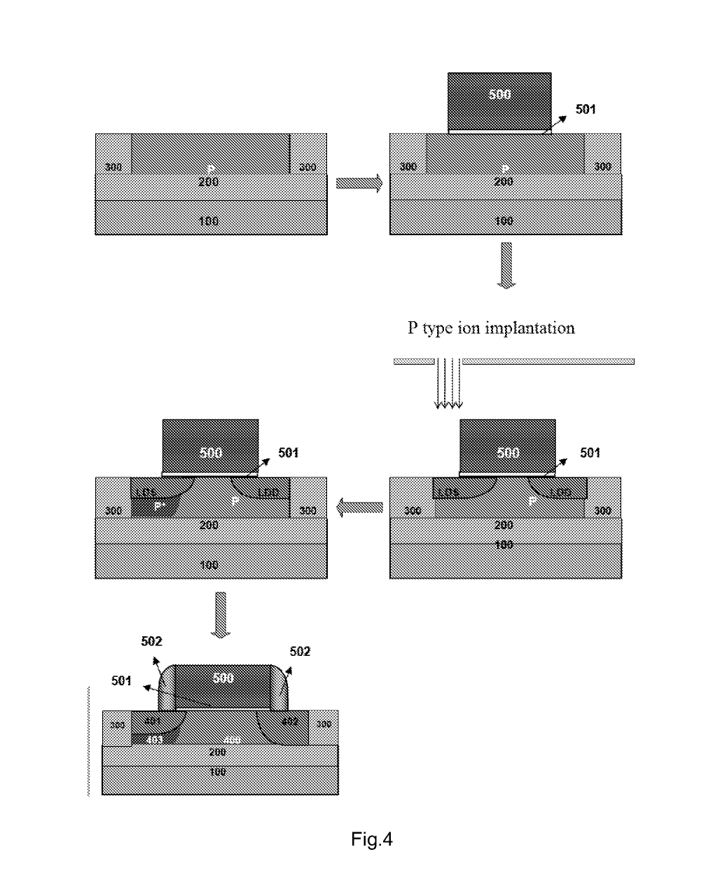

Referring to FIG. 4 of the drawings, this example provides a second method of manufacturing MOS structure with suppressed floating body effect comprises the following steps.

Firstly, create a shallow trench isolation structure 300 on a semiconductor material, such as SOI (silicon on insulator) or GOI (germanium on insulator), having a buried insulation layer 200, to isolate an active area, and implant P ion into the active area. Create a gate dielectric layer 501 and gate electrode 500. Lightly dope a source region and a drain region. Add a mask on the active area, create an opening on the mask at a position of a first conductive type source region 401, and vertically highly implant P ions into the active area into via the mask forming a highly doped P region under the lightly doped source region. Implant N ions into the source region and source region forming a first conductive type region 401 and a first conductive type drain region 402 and a body region 400 between the first conductive type region 401 and the first conductive type drain region 402. Form a second conductive type region 403 between the first conductive type region 401 and the buried insulation layer 200. Produce an insulation dielectric spacer 502 around the gate region.

### Example III

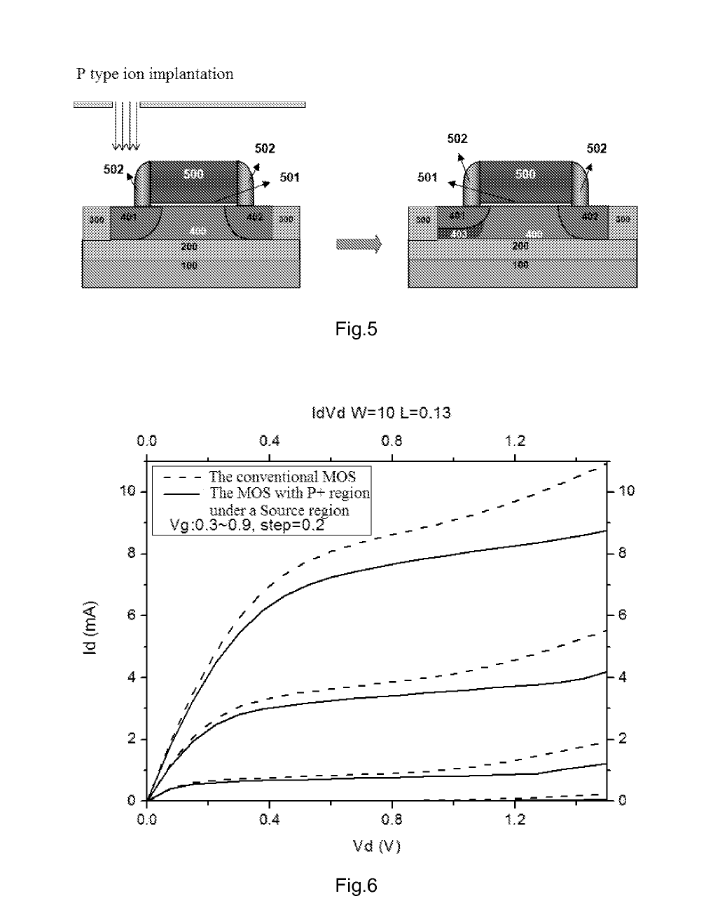

Referring to FIG. 5 of the drawings, this example provides a third method of manufacturing MOS structure with suppressed floating body effect comprises the following steps. Form a body region 400 on a semiconductor material, such as SOI (silicon on insulator) or GOI (germanium on insulator), having a buried insulation layer 200, a first conductive type source region 401 and a first conductive type drain region 402 provided on both sides of the body region 400 respectively, and a gate region on the body region 400 including a gate dielectric layer 501, a gate electrode 500 and an insulation dielectric spacer 502. Add a mask on the first conductive type source region 401, vertically highly implant P ions into the first conductive type source region 401 to form a high doped second conductive type region 403 under the first conductive type region 401 and on the buried insulation layer 200.

In order to analyze the performance of the MOS of the present invention, a simulation is performed. The result shows that the present invention can effectively suppress the floating body effect of the MOS on the SOI. FIG. 6 shows an I_{d}-V_{d} contrast chart of 0.13 μm device. The dashed line represents the curve of the traditional MOS on the SOI, wherein Kink effect is obvious. The solid line represents the curve of the MOS on the SOI of the present invention. It can be seen that the kink voltage is postponed after the operating voltage, that is to say, the kink voltage is lowered at the operating voltage of the device, so that the Kink effect is suppressed.

The above description of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A MOS structure with suppressed floating body effect, comprising:
a substrate,
a buried insulation layer provided on the substrate, and
an active area provided on the buried insulation layer comprising a body region, a first conductive type source region and a first conductive type drain region provided on both sides of the body region respectively and a gate region provide on top of the body region,
wherein the active area further comprises a highly doped second conductive type region between the first conductive type source region and the buried insulation layer, and the highly doped second conductive type region contacts to the first conductive type source region, the buried insulation layer and the body region respectively.

2. The MOS structure with suppressed floating body effect, as recited in claim 1,
wherein a shallow trench isolation structure is provided surrounding the active area.

3. The MOS structure with suppressed floating body effect, as recited in claim 1,
wherein the gate region comprises a gate dielectric layer and a gate electrode 500 provided on the gate dielectric layer.

4. The MOS structure with suppressed floating body effect, as recited in claim 1,
wherein an insulation dielectric spacer is provided around the gate region.

5. The MOS structure with suppressed floating body effect, as recited in claim 1,
wherein the first conductive type source region adopts highly doped N type semiconductor material.

6. The MOS structure with suppressed floating body effect, as recited in claim 1,
wherein the first conductive type drain region adopts highly doped N type semiconductor material.

7. The MOS structure with suppressed floating body effect, as recited in claim 1,
wherein the highly doped second conductive type region adopts high doped P type semiconductor material.

8. The MOS structure with suppressed floating body effect, as recited in claim 1,
wherein the body region adopts P type semiconductor material.

9. The MOS structure with suppressed floating body effect, as recited in claim 1,
wherein the buried insulation layer is buried oxide layer.
